(19) United States
(12) Patent Application Publication
(10) Pub. No.: US 2012/0037212 A1
(43) Pub. Date: Feb. 16, 2012

(54) PHOTOVOLTAIC MODULE AND METHOD FOR THE PRODUCTION THEREOF

(75) Inventor: Harry Wirth, Merzhausen (DE)

(73) Assignee: Frunhofer-Gesellschaft zur Foerderung Der Angewandten Forschlung E.V., Munkch (DE)

(21) Appl. No.: 13/138,422

(22) PCT Filed: Feb. 15, 2010
(86) PCT No.: PCT/EP2010/000919

§ 371 Date: Oct. 24, 2011

(30) Foreign Application Priority Data
Feb. 16, 2009 (DE) 102009009036.3

(51) Int. Cl. H01L 31/048; H01L 31/18

(52) U.S. Cl. 136/251; 438/73; 257/E31.001

(57) ABSTRACT

The invention relates to a photovoltaic module comprising a first and a second cover layer, an arrangement situated between these of photovoltaic cells which are connected via cell connectors and also an edge seal of the cover layers which extends around the photovoltaic module. The module according to the invention thereby makes possible minimization of the mechanical stresses, e.g. due to different coefficients of thermal expansion, of the photovoltaic cells. Likewise, a method for production of the photovoltaic modules according to the invention is provided.

The invention relates to a photovoltaic module comprising a first and a second cover layer, an arrangement situated between these of photovoltaic cells which are connected via cell connectors and also an edge seal of the cover layers which extends around the photovoltaic module. The module according to the invention thereby makes possible minimisation of the mechanical stresses, e.g. due to different coefficients of thermal expansion, of the photovoltaic cells. Likewise, a method for production of the photovoltaic modules of the invention is provided.

Wafer-based solar cells must be disposed between protective cover layers. Their fixing must take into account the different thermal coefficients of expansion between cover layer materials, in particular glass, and the wafer material, silicon. Finally, the production process of the solar module must satisfy economic requirements with respect to material and processing costs.

In the state of the art, this object is achieved by an encapsulation material which surrounds the cells on both sides and connects to the cover layers made of glass or rear-side foils/glass. The cells are connected electrically before encapsulation so that cell strings and finally a cell matrix are produced.

A disadvantage of the method is increased Material consumption, a delay in the production process due to the laminating step and an increased risk of breakage of the cells in the module when using thin wafers.

The teaching of WO 2004/095586 dispenses with the encapsulation in favour of fixing the cells by means of vacuum pressure between the cover layers and a seal only at the edge. The question of endurance of the vacuum and also of the contact points between glass, cells and cell connectors are still unclear.

DE 197 52 678 A1 describes an embodiment without encapsulation material, in which the cells are fixed at points on the cover layer. The minimum spacing of the two cover layers is not described. Furthermore, because of the different coefficients of thermal expansion between cells and glass, the fixing points must have a thickness which impedes the heat dissipation of the cells.

Starting herefrom, it was the object of the present invention to eliminate the disadvantages known from the state of the art and to provide photovoltaic modules which enable minimum mechanical loading of the photovoltaic cells and thereby reduce the production complexity required for this purpose.

This object is achieved by the photovoltaic module having the features of claim 1 and also by the method for production thereof having the features of claim 16. The further dependent claims reveal advantageous developments.

According to the invention, a photovoltaic module is provided which has a first and a second cover layer, an arrangement situated between these of photovoltaic cells which are connected via cell connectors and also an edge seal of the cover layers which extends around the photovoltaic module. The photovoltaic module thereby has at least one localised contact element (LKE), which forms a space between the two cover layers. Furthermore, at least one photovoltaic cell or at least one cell connector is connected integrally via at least one LKE to at least one cover layer. A further feature of the module according to the invention is that at least one photovoltaic cell has at least one LKE which is connected integrally and/or is disposed in sliding contact in order to form a spacing relative to the at least one cover layer.

The solution according to the invention describes a module construction wherein, in contrast to the state of the art, a volume-filling encapsulation between the cover layers is dispensed with. Rather, use of material at points is effected (so-called localised contact elements, LKE) for fixing, spacing and possibly reinforcing, in the case of an otherwise gas-filled module which is sealed at the edge.

The invention is based on the basic concept of fixing the cells via respectively one rigid connection at most such that thermal expansion differences between cell and cover layer do not lead to critical stresses. This can be achieved for example by a single adhesion point between photovoltaic cell and cover layer, the remainder of the cell surface being freely movable in the tangential direction.

Preferably, at least one LKE has a sliding bearing for production of a sliding contact with cover layers, photovoltaic cells and/or cell connectors and a stationary bearing for integral connection to cover layers, photovoltaic cells and/or cell connectors. The integral connection of these stationary bearings is thereby based preferably on physical and/or chemical interactions. There are included herein for example adhesive, solder or weld connections.

For a local contact element which has a sliding bearing, it is preferred if the cross-section of the LKE tapers towards the sliding bearing. This enables a certain movability of the local contact element.

The localised contact element consists of or comprises preferably an organic or inorganic elastomer, e.g. also a foamed material, for compensation of spacing changes between the cover layers.

The localised contact element preferably has a thickness in the range of 0.001 to 5 mm, preferably of 0.01 to 0.5 mm and particularly preferred of 0.1 to 0.3 mm.

The localised contact element can thereby preferably be connected to both cover layers and to one photovoltaic cell or, in a further preferred embodiment, to both cover layers and to one cell connector.

The surface expansion of the LKE on the photovoltaic cell constitutes preferably a surface proportion of ≦10%, preferably ≦5% and particularly preferred ≦2%, of the photovoltaic cell.

It is preferred furthermore that the first cover layer and the localised contact elements which are situated between the first cover layer and the photovoltaic cells are essentially transparent in the wavelength range of 300 to 1,200 nm so that solar radiation can impinge on the solar cells without interference.

The cell connectors between the photovoltaic cells are preferably connected electrically and mechanically to the photovoltaic cells. It is hereby also possible that the cell connector represents a stress-relieving element which enables compensation of lateral movements of the photovoltaic cells. There are included herein elements having an at least one-dimensional spring effect. The stress-relieving element can thereby preferably be arcuate, s-shaped and/or angled.

A further preferred embodiment provides that a localised contact element, which is in contact with both cover layers, is connected to a stress-relieving element which is disposed over at least two connection points to at least two adjacent solar cells. Stress-relieving elements which are connected to cell connectors reduce the effect of force on the photovoltaic cell, for example due to differential thermal expansion or module deflection.

Preferably, the localised contact elements for spacing the cover layers are dimensioned such that they prevent direct contact of the cover layers with the photovoltaic cells under normal pressure loads.

A further preferred embodiment provides that at least one localised contact element connects a cell connector to a cover layer such that no integral connection between cell connector and photovoltaic cell exists in the immediate vicinity of the contact point on the cell connector.

Basically, the photovoltaic module according to the invention hence has different localised contact elements which differ with respect to the type of contact with the other components.

For the fixing, the localised contact element can be an element which is adhesive on both sides or purely an adhesive compound which produces integral connections between cell and cover layer. The adhesion point(s) are situated inside a small, compact surface cut-out, as a result of which differences in the coefficients of thermal expansion between cell and cover layer can be compensated for even with very thin adhesive layers.

A second variant of the localised contact element configured as adhesion element relates to connections of cell connector and cover layer.

The localised contact elements, the function of which is the spacing of the cover layers, have sliding places and/or adhesion places. If such localised contact elements are disposed in the region of a photovoltaic cell, then a sliding place can be provided on the oppositely situated side to the adhesion place. It is thus ensured that the photovoltaic cell experiences merely vertical pressure forces in the case of slight deformation/displacement of the cover layers, as a result of which no notable shear forces occur.

If the localised contact elements for the spacing of the cover layers are disposed in the region between the photovoltaic cells, then a sliding- or adhesion place can be configured directly between both cover layers. By means of adhesion places, the bond of the cover layers can be reinforced in addition, whereas the bond remains loose in the case of purely sliding places.

Fixing of the cells at a small spacing relative to the first cover layer is preferred in order to facilitate the heat dissipation.

It is advantageous for the power of the module,
to dispose the cells at a small spacing relative to the cover layers, in particular relative to the upper cover layer, because the heat can then be conducted better to the outside and the cell temperature remains lower,
to provide the upper cover layer with reflection-reducing properties (coating, structuring) on both sides,
to coat the cells antireflectively relative to gas, i.e. a medium with refractive index 1.

According to the invention, a method for the production of a photovoltaic module, as was described previously, is likewise provided in which the localised contact elements in liquid or pasty form are applied on at least one cover layer and at least one photovoltaic cell and subsequently are cured thermally or photochemically. The localised contact elements in liquid or pasty form are thereby preferably printed, sprayed and/or metered.

The subject according to the invention is intended to be explained in more detail with reference to the subsequent Figures, without wishing to restrict said subject to the special embodiments shown here.

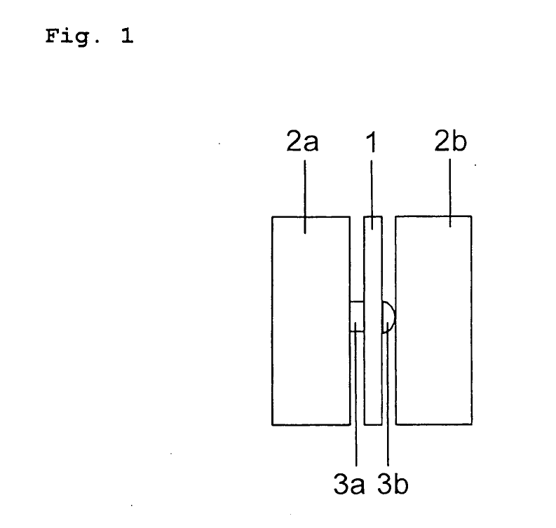

FIG. 1 shows a variant according to the invention in cross-section.

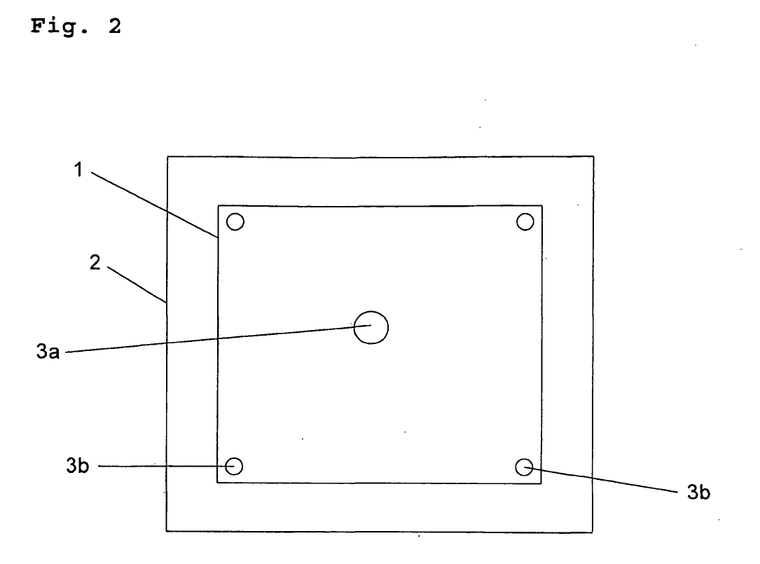

FIG. 2 shows a variant according to the invention in plan view.

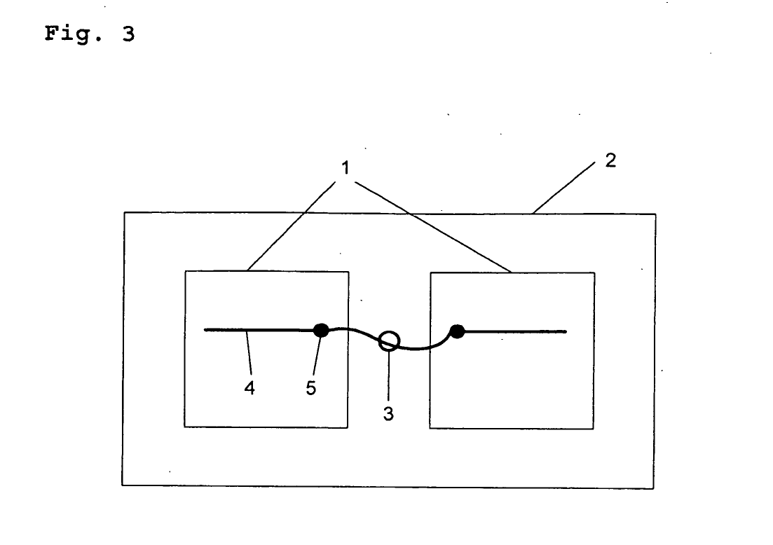

FIG. 3 shows a further variant according to the invention in plan view.

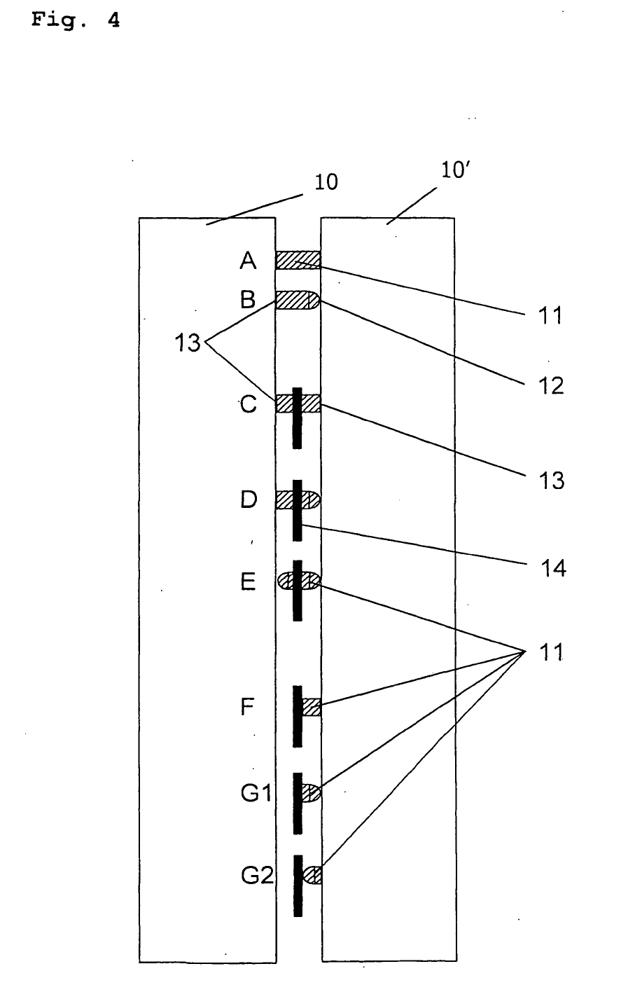

FIG. 4 shows various variants for localised contact elements which are integrated in a single system in a schematic representation.

FIG. 1 shows a preferred embodiment in cross-section, having a cell 1, the cover layers 2a and 2b, a localised contact element with adhesion properties 3a and a localised contact element with sliding properties 3b. The sliding element is situated behind the adhesion element and consequently transmits pressure loads between the cover layers perpendicular to the cell surface. Shear stresses on the cell are avoided by means of the sliding surface.

The localised contact element with adhesion properties 3a can be configured as carrier-free adhesive film, the localised contact element with sliding properties 3b as foamed polymer with an adhesive layer disposed on one side. FIG. 2 shows a preferred embodiment in plan view having a cell 1, a cover layer 2 situated thereunder, a centrally disposed localised contact element with adhesive properties 3a relative to the cover layer situated in front, and also four localised contact elements with sliding properties 3b.

FIG. 3 shows a preferred embodiment in which the cell connector 4 between its first connection point 5 to the cell and the adhesion element 3 is provided with a (here arcuate) stress-relieving element. The cell connector 4 is fixed on a cover layer 2 via the adhesion element 3. The adhesion element 3 can form a space between the two cover layers at the same time and/or can connect the two cover layer to each other securely so that reinforcement of the bond is effected.

The localised contact element with adhesion properties between cell connector and cover layer can also be disposed in the region of the cell. Optionally, it can coincide in addition with a connection point between cell connector and cell.

Various variants for the arrangement of localised contact elements are represented in FIG. 4. Between the cover layers 10 and 10′ in variant A, firstly a local contact element 11 is represented, which has adhesion properties at both ends and thus enables an integral connection to the cover layers. Variant B shows a local contact element which has a sliding bearing 12 on the one side and an integrally connected stationary bearing 13 on the other side. It is thereby advantageous if the cross-section of the local contact element tapers towards the sliding bearing 12. Variant C represents a local contact element with stationary bearing 13 at both ends, in which a solar cell or a cell connector 14 is integrated. Variant D differs from the variant C by the local contact element having a sliding bearing 12 on the one surface. Variant E differs from variant D by the localised contact element having two sliding surfaces here. In variant F, the solar cell or a cell connector 14 are mounted on a cover layer by means of a local contact element 11, the local contact element having stationary bearings on both sides. Variants G1 and G2 differ from variant F by the localised contact element here having a sliding bearing 12 towards the cover layer or towards the solar cell or towards the cell connector.

1-17. (canceled)

18. A photovoltaic module comprising a first and a second cover layer, an arrangement situated between these of photovoltaic cells which are connected via cell connectors and also an edge seal of the cover layers which extends around the photovoltaic module, wherein the module has at least one localised contact element (LKE), which forms a space between the two cover layers, at least one photovoltaic cell or at least one cell connector is connected integrally via at least one LKE to at least one cover layer and in that at least one photovoltaic cell has at least one LKE which is connected integrally and/or is disposed in sliding contact in order to form a spacing relative to at least one cover layer.

19. The photovoltaic module according to claim 18, wherein the at least one LKE has a sliding bearing for production of a sliding contact and a stationary bearing for integral connection to cover layers, photovoltaic cells and/or cell connectors.

20. The photovoltaic module according to claim 18, wherein the integral connection of the stationary bearings is based on physical and/or chemical interactions, in particular an adhesive, a solder or a weld connection.

21. The photovoltaic module according to claim 18, wherein the LKE consist of an organic or inorganic elastomer, preferably a foamed material, for compensation of spacing changes between the cover layers or comprises this.

22. The photovoltaic module according to claim 18, wherein the LKE have a thickness in the range of 0.001 to 5 mm, preferably of 0.01 to 0.5 mm and particularly preferred of 0.1 to 0.3 mm.

23. The photovoltaic module according to claim 18, wherein at least one LKE is connected to both cover layers and to one photovoltaic cell or to one cell connector.

24. The photovoltaic module according to claim 18, wherein the surface expansion of the LKE on the photovoltaic cell constitutes preferably a surface proportion of ≦10%, preferably ≦5% and particularly preferred ≦2%, of the photovoltaic cell.

25. The photovoltaic module according to claim 18, wherein the first cover layer and the LKE which are situated between the first cover layer and the photovoltaic cells are essentially transparent in the wavelength range of 300 to 1,200 nm.

26. The photovoltaic module according to claim 18, wherein the cell connector is connected electrically and mechanically to the photovoltaic cell.

27. The photovoltaic module according to claim 18, wherein the cell connector is a stress-relieving element which enables compensation of lateral movements of the photovoltaic cells, in particular an element having an at least one-dimensional spring effect.

28. The photovoltaic module according to claim 27, wherein the stress-relieving element is arcuate, s-shaped or angled in order to provide the at least one-dimensional spring effect.

29. The photovoltaic module according to claim 27, wherein at least one localised contact element, which is in contact with both cover layers, is connected to a stress-relieving element which is disposed over at least two connection points to at least two adjacent solar cells.

30. The photovoltaic module according to claim 18, wherein the at least one local contact element has a sliding bearing and has a cross-section tapering towards the sliding bearing.

31. The photovoltaic module according to claim 18, wherein the LKE are dimensioned for the spacing of the cover layers such that they prevent a direct contact of the cover layers with the photovoltaic cells under normal pressure loads.

32. The photovoltaic module according to claim 18, wherein at least one LKE connects a cell connector to a cover layer such that no integral connection between cell connector and photovoltaic cell exists in the immediate vicinity of the contact point on the cell connector.

33. A method for the production of a photovoltaic module according to claim 18, in which the localised contact elements in liquid or pasty form are applied on at least one cover layer and at least one photovoltaic cell and subsequently are cured thermally or photochemically.

34. The method according to claim 33, wherein the localised contact elements are printed, sprayed and/or metered.
